(19) United States
(12) Patent Application Publication
(10) Pub. No.: US 2006/0125046 A1
(43) Pub. Date: Jun. 15, 2006

(54) Integrated inductor and method of fabricating the same

(76) Inventors: Hyun Cheol Bae, Yuseong-gu (KR); Dong Woo Suh, Yuseong-gu (KR); Jin Yeong Kang, Yuseong-gu (KR)

Correspondence Address: LADAS & PARRY LLP, 224 SOUTH MICHIGAN AVENUE, SUITE 1600, CHICAGO, IL, 60604, US

(21) Appl. No.: 11/237,237

(22) Filed: Sep. 28, 2005

(30) Foreign Application Priority Data
Dec. 14, 2004 (KR) 2004-105800
Apr. 6, 2005 (KR) 2005-28368

(51) Int. Cl. H01L 29/00; H01F 5/00

(52) U.S. Cl. 257/531; 257/528; 336/200

(57) ABSTRACT

Provided are an integrated inductor and a method of manufacturing the same. The integrated inductor includes: a silicon on insulator (SOI) wafer on which a substrate, an oxide layer, and an active layer are stacked; a first metal interconnection formed in a predetermined region on the SOI wafer; a second metal interconnection electrically connected to the first metal interconnection; and a first interlayer insulating layer formed between the first and second metal interconnections so as to make the first and second metal interconnections spaced from each other by a constant interval, so that the quality factor Q can be enhanced, a frequency where the maximum quality factor Q occurs can be adjusted to a desired band, a leakage current to the substrate can be prevented from occurring, and heat within the inductor can be suppressed from occurring.

### CROSS-REFERENCE TO RELATED APPLICATION

This application claims priority to and the benefit of Korean Patent Application No. 2004-105800, filed Dec. 14, 2004 and Korean Patent Application No. 2005-28368, filed Apr. 6, 2005, the disclosure of which is incorporated herein by reference in its entirety.

### BACKGROUND

1. Field of the Invention

The present invention relates to an integrated inductor as a component of a monolithic microwave integrated circuit (MMIC) which is essential in manufacturing a chip on which radio frequency (RF)/analog/digital ICs are integrated, i.e., a system-on-chip (SoC) for telecommunication and a method of manufacturing the same, and more particularly, to an integrated inductor capable of preventing a leakage current to a substrate and suppressing heat from occurring within the inductor and a method of manufacturing the same.

2. Discussion of Related Art

In general, many researches have been conducted to implement one-chip of an analog/digital integrated circuit and a radio frequency integrated circuit (RF IC) as a RF element, which are accompanied by researches on an inductor having a reduced volume and a high quality factor (Q), and MMIC technology is spotlighted as the most suitable technology for manufacturing a chip on which the RF/analog/digital ICs are integrated, i.e., a system-on-chip (SoC).

The MMIC technology allows an active element including a transistor, and an inductor, a capacitor, a resistor or the like to be integrated within one chip, and among these elements, the inductor occupying the largest area within the chip has a significant influence.

SiGe bipolar complementary metal oxide semiconductor (SiGe BiCMOS) technology is spotlighted as the most suitable technology for manufacturing the chip on which the RF/analog/digital ICs are integrated (SoC). Such a SiGe BiCMOS technology has a SiGe hetero junction bipolar transistor (HBT) suitable for the RF/analog circuit, and a CMOS suitable for the digital circuit integrated on one substrate, and it is the main stream that a silicon on insulator (SOI) substrate is used for the CMOS for implementing low power consumption.

To enhance a quality factor (Q) characteristic using an integrated thin film inductor, conventional methods have been proposed, which include a method of adding a plating process to a simple type inductor or an improved type inductor to make a metal line thick, a method of manufacturing a three-dimensional inductor using a bonding wire, or a method of simply connecting a double-layer and a triple-layer with many vias after forming a multi-layered metal line of three layers or more, and increasing the cross-sectional area of the metal line to enhance the quality factor Q by decreasing a resistance of the inductor.

However, all of the above-described conventional methods suffer from problems such as a difficulty in manufacture, an increase in manufacturing unit cost, less reproducibility, absence of compatibility with a general semiconductor process, in particular, a process based on silicon, a delay in manufacturing time, and so forth.

### SUMMARY OF THE INVENTION

The present invention is directed to an integrated inductor and a method of manufacturing the same, which can maximize a mutual inductance between a metal interconnection and a magnetic inductance occurring from the used metal interconnection while maintaining compatibility with other processes to have high reliability and good quality factor (Q) characteristics without requiring an additional process, and can adjust a frequency so as to generate the maximum quality factor (Q) in an arbitrary frequency band without decreasing the inductance obtained from a shape of the given upper metal interconnection, so that a parasitic resistance to the substrate can be reduced, a leakage current can be prevented from occurring, and heat within the inductor can be suppressed from occurring.

One aspect of the present invention is to provide an integrated inductor including: a silicon on insulator (SOI) wafer on which a substrate, an oxide layer, and an active layer are stacked; a first metal interconnection formed in a predetermined region on the SOI wafer; a second metal interconnection electrically connected to the first metal interconnection; and a first interlayer insulating layer formed between the first and second metal interconnections so as to make the first and second metal interconnections spaced from each other by a constant interval.

Another aspect of the present invention is to provide a method of manufacturing an integrated inductor, which includes: (a) forming a silicon on insulator (SOI) wafer on which a substrate, an oxide layer, and an active layer are stacked; (b) forming a first metal interconnection in a predetermined region on the SOI wafer; (c) forming a first interlayer insulating layer pattern that surrounds the first metal interconnection such that a predetermined region on the first metal interconnection is exposed; and (d) forming a second metal interconnection connected to the exposed first metal interconnection.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a plan view for explaining an integrated inductor in accordance with an embodiment of the present invention;

FIG. 2 is a perspective view for explaining an integrated inductor in accordance with an embodiment of the present invention; and

FIGS. 3A to 3D are cross-sectional views for explaining an integrated inductor in accordance with an embodiment of the present invention.

### DETAILED DESCRIPTION OF PREFERRED EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure is thorough and complete and fully conveys the scope of the invention to those skilled in the art. Like numbers refer to like elements throughout the specification.

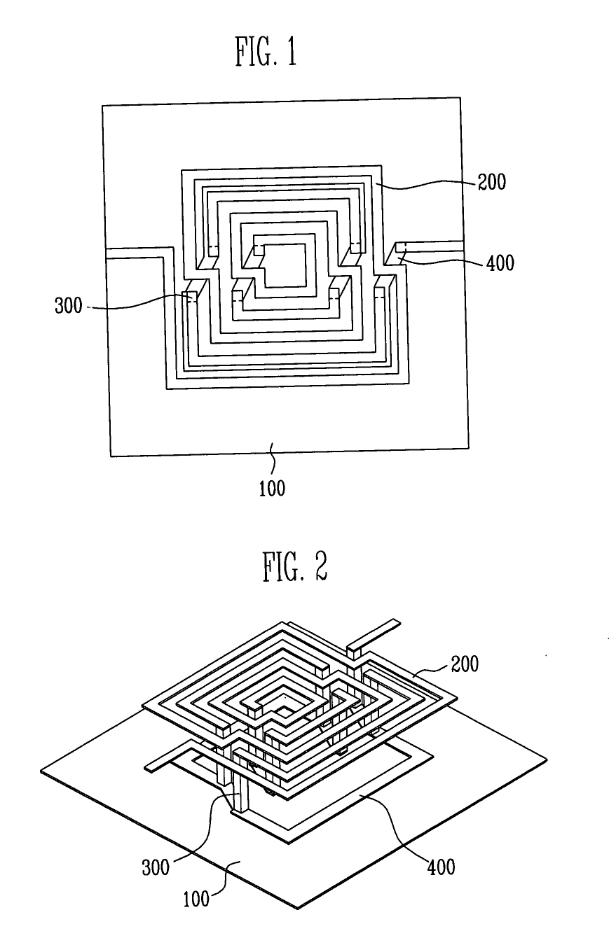

FIG. 1 is a plan view for explaining an integrated inductor in accordance with an embodiment of the present invention, and FIG. 2 is a perspective view for explaining an integrated inductor in accordance with an embodiment of the present invention.

Referring to FIGS. 1 and 2, the integrated inductor according to an embodiment of the present invention includes a silicon on insulator (hereinafter referred to as an “SOI”) wafer 100, a first metal interconnection 200, a first interlayer insulating layer 300, and a second metal interconnection 400.

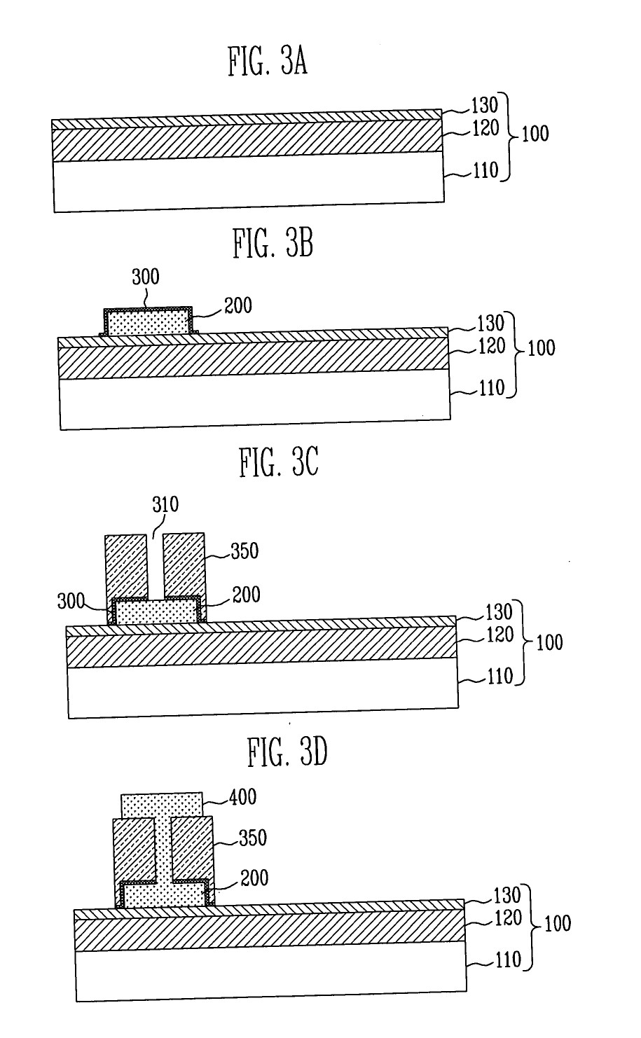

In this case, the SOI wafer 100 is configured to have a substrate 110, an oxide layer 120, and an active layer 130 stacked as shown in FIGS. 3A to 3D to be described later.

The first metal interconnection 200 is formed in a predetermined region on the SOI wafer 100. By way of example, the first metal interconnection is preferably formed of a material such as aluminum (Al), titanium (Ti), and titanium nitride (TiN).

In the meantime, the first metal interconnection 200 according to the embodiment of the present invention is implemented to have a spiral square shape, however, not limited thereto, but may also be implemented in a spiral circle or spiral polygon shape.

A plurality of first interlayer insulating layers 300, for example, each having a square pillar shape are formed to be spaced apart from each other in a predetermined region between the first and second metal interconnections 200 and 400. Such a first interlayer insulating layer 300 has a predetermined via hole 310 (see FIG. 3C) so as to make the first and second metal interconnections 200 and 400 spaced by a predetermined interval and electrically connected to each other.

In addition, the first interlayer insulating layer 300 is an interlayer-metal dielectric (IMD) oxide material, and for example, is preferably formed of an oxide layer.

In the meantime, a second interlayer insulating layer 350 (see FIGS. 3A to 3D) having a predetermined thickness may additionally formed between the first metal interconnection 200 and the first interlayer insulating layer 300. Such a second interlayer insulating layer 350 is preferably formed of, for example, a SiOₓN_{y} material.

The second metal interconnection 400 is electrically connected to the first metal interconnection 200 through the via hole 310.

Such a second metal interconnection 400 has the same shape as the above-described first metal interconnection 200, and is preferably formed of a material such as Al, Ti, and TiN.

In the meantime, the first and second metal interconnections 200 and 400 are arranged to be parallel to each other or to make a current flow equal to each other, and are preferably formed so as to have an electrically parallel-branched shape.

According to the structure of the integrated inductor of the embodiment of the present invention, a square-shaped lower metal interconnection, that is, the first metal interconnection 400 parallel to the second metal interconnection 400 is parallel-branched via the predetermined via hole 310 when the inductor is produced using an upper metal interconnection, that is, the second metal interconnection 400 for adjusting a frequency producing the maximum quality factor (Q) to a desired frequency band while generating a good quality factor in a substrate such as an SOI CMOS substrate which has been increasingly employed because of its low power consumption.

By means of such a method, the quality factor Q can be enhanced, and a location of the frequency having the maximum quality factor Q occurred can be adjusted.

The second metal interconnection 400 is in charge of forming most of the inductance, however, the first metal interconnection 200 may be arranged to have a square shape parallel to the second metal interconnection 400 to enhance the quality factor (Q) by simultaneously forming a self-inductance of the first metal interconnection 200 by itself, a mutual inductance between the parallel first metal interconnections 200, and a mutual inductance produced by a parallel part between the first and second metal interconnections 200 and 400.

In addition, the first metal interconnection 200 and the second metal interconnection 400 are electrically connected parallel to each other, so that the resistance of the metal interconnection in a section branched parallel to each other significantly decreases, thereby compensating for an occurrence of parasitic capacitance resulted from the arrangement of the first metal interconnection 200, and a decrease in quality factor (Q).

In addition, a parallel area of the first metal interconnection 200 and the second metal interconnection 400 can be arbitrarily adjusted, so that a capacitance component resulted from the first metal interconnection 200 can be adjusted to a desired one, which allows a frequency band having the maximum quality factor (Q) determined by the capacitance component and the resistance component of the metal interconnection to be arbitrarily adjusted.

In addition, since the parallel-branched inductor is implemented on the SOI wafer 100, a parasitic resistance to the substrate can be reduced, a leakage current can be prevented from occurring, and heat within the inductor can be suppressed from occurring.

FIGS. 3A to 3D are cross-sectional views for explaining an integrated inductor in accordance with an embodiment of the present invention.

Referring to FIG. 3A, an SOI substrate 100 in which a substrate 110, an oxide layer 120, and an active layer 130 are stacked is formed.

In this case, the substrate 110 is a p-type and has a value of about 6 to 100 Ω·cm. A high resistance substrate is a lightly doped substrate so that it has good performance because of its low substrate capacitance, however, it is too expensive.

The oxide layer 120 is formed to a thickness of about 0.3 μm to about 2 μm, however, the SOI having a thick insulating layer is expensive.

The active layer 130 is preferably formed to a thickness of about 500 Å to about 1000 Å.

Referring to FIG. 3B, a material such as Al/Ti/TiN is used to form the first metal interconnection 200 in a predetermined region on the SOI wafer 100, and a second interlayer insulating layer 350 made of, for example, a SiOₓN_{y} material is formed so as to surround the first metal interconnection 200. This second interlayer insulating layer 350 may be omitted if necessary.

In the meantime, the first metal interconnection 200 is preferably formed in a spiral square shape, a spiral circle shape, a spiral polygon shape, or the like.

Referring to FIG. 3C, a first interlayer insulating layer 300 is formed to a predetermined thickness on the second interlayer insulating layer 350, and a via hole 310 having a predetermined width is then formed in a predetermined region of the first and second interlayer insulating layers 300 and 350 using a predetermined etch mask such that a predetermined region of the first metal interconnection 200 is exposed.

In this case, the first interlayer insulating layer 300 is an IMD oxide material, and, for example, is preferably formed of an oxide layer.

Referring to FIG. 3D, a second metal interconnection 400 is formed on the first interlayer insulating layer 300 and the first metal interconnection 200 exposed through the via hole 310. Accordingly, the second metal interconnection 400 is electrically connected to the first metal interconnection 200 through the via hole 310.

In this case, the second metal interconnection 400 preferably has the same shape as the first metal interconnection 200 using a material such as Al, Ti, and TiN.

According to the integrated inductor and the method of manufacturing the same as described above, a substrate loss characteristic of the parallel-branched inductor is improved using the SOI process for improving the characteristics of the inductor technology necessary for manufacturing a chip on which radio frequency (RF)/analog/digital ICs are integrated, i.e., a system-on-chip (SoC) for telecommunication as a semiconductor element for telecommunication, and a method of forming the parallel-branched inductor using the SOI substrate which is actively under research using a nano-class CMOS element process is provided.

In addition, according to the present invention, the parallel branched inductor for the SOI device is formed in a substrate such as an SOI CMOS substrate which has been increasingly employed when manufacturing the nano-class element for low power consumption, so that a loss of the substrate resistance can be reduced, and a chip on which the radio frequency (RF)/analog/digital ICs are integrated, i.e., a system-on-chip (SoC) which can operate with low voltage/low power can be implemented.

In addition, according to the present invention, the first and second metal interconnections are arranged parallel to each other, and an area of the parallel part can be arbitrarily adjusted, so that the frequency allowing the quality factor Q to be enhanced and the maximum quality factor Q to occur can be adjusted to a desired band, which has high compatibility with the conventional semiconductor process and other processes, and can have good reliability only with a simple structure.

Although the integrated inductor and the method of manufacturing the same of exemplary embodiments of the present invention have been described, the present invention is not limited to these embodiments, and it should be appreciated to those skilled in the art that a variety of modifications and changes can be made without departing from the spirit and scope of the present invention.

What is claimed is:

1. An integrated inductor, comprising:
a silicon on insulator (SOI) wafer on which a substrate, an oxide layer, and an active layer are stacked;
a first metal interconnection formed in a predetermined region on the SOI wafer;
a second metal interconnection electrically connected to the first metal interconnection; and
a first interlayer insulating layer formed between the first and second metal interconnections so as to make the first and second metal interconnections spaced from each other by a constant interval.

2. The integrated inductor according to claim 1, wherein the first interlayer insulating layer is formed of an inter-metal dielectric (IMD) oxide material.

3. The integrated inductor according to claim 1, further comprising:
a second interlayer insulating layer having a predetermined thickness and formed between the first metal interconnection and the first interlayer insulating layer.

4. The integrated inductor according to claim 3, wherein the second interlayer insulating layer is formed of a SiOₓN_{y} material.

5. The integrated inductor according to claim 1, wherein the first and second metal interconnections have one selected from a spiral square shape, a spiral circle shape, and a spiral polygon shape, and are arranged parallel to each other.

6. The integrated inductor according to claim 1, wherein the first metal interconnection is arranged so as to have a current flow equal to that of the second metal interconnection.

7. The integrated inductor according to claim 1, wherein the first metal interconnection and the second metal interconnection are electrically parallel-branched through a via hole formed in the first interlayer insulating layer.

8. A method of manufacturing an integrated inductor, comprising:
(a) forming a silicon on insulator (SOI) wafer on which a substrate, an oxide layer, and an active layer are stacked;
(b) forming a first metal interconnection in a predetermined region on the SOI wafer;
(c) forming a first interlayer insulating layer pattern that surrounds the first metal interconnection so as to expose a predetermined region on the first metal interconnection; and
(d) forming a second metal interconnection connected to the exposed first metal interconnection.

9. The method according to claim 8, wherein the first interlayer insulating layer pattern is formed of an inter-metal dielectric (IMD) oxide material.

10. The method according to claim 8, further comprising:
forming a second interlayer insulating layer pattern having a predetermined thickness and surrounding the first metal interconnection such that a predetermined region on the first metal interconnection is exposed after carrying out the step (b).

11. The method according to claim 10, wherein the second interlayer insulating layer pattern is formed of a SiOₓN_{y} material.

12. The method according to claim 8, wherein the step (c) includes:
(c-1) forming a first interlayer insulating layer having a predetermined thickness so as to surround the first metal interconnection; and
(c-2) forming a first interlayer insulating layer pattern that forms a via hole by etching the first interlayer insulating layer such that a predetermined region of the first metal interconnection is exposed,
wherein the step (d) includes forming a second metal interconnection on the first metal interconnection and the first interlayer insulating layer exposed through the via hole.
